(19) United States
(12) Patent Application Publication
(10) Pub. No.: US 2019/0048457 A1
(43) Pub. Date: Feb. 14, 2019

(54) EVAPORATION SOURCE

(71) Applicant: Wuhan China Star Optoelectronics Techology Co., Ltd, Wuhan (CN)

(72) Inventors: Zhan SHI, Wuhan (CN); Donghwan KIm, Wuhan (CN); Xuwen Cao, Wuhan (CN); Youngsu Kim, Wuhan (CN); Zhihua Hong, Wuhan (CN)

(21) Appl. No.: 15/566,709

(22) PCT Filed: May 3, 2017
(86) PCT No.: PCT/CN2017/082810

§ 371 Date: Oct. 15, 2017

(30) Foreign Application Priority Data
Mar. 29, 2017 (CN) 201710200249.0

(51) Int. Cl. C23C 14/24; C23C 14/26; C23C 14/54; C23C 14/12

(52) U.S. Cl. CPC C23C 14/243; C23C 14/26; H01L 51/001; C23C 14/12; C23C 14/543

(57) ABSTRACT

An evaporation source includes a casing, a crucible configured to receive evaporation material, a spray nozzle, a first heating wire, and a lifting mechanism. The casing includes a first end, a second end opposite the first end, and a transmission chamber disposed between the first end and the second end. The evaporation material forms a heating surface on a surface in the crucible when the evaporation material is heated in the crucible. The crucible is disposed in the casing and is positioned at the second end. The crucible is in communication with the transmission chamber. The spray nozzle is disposed at the first end and is in communication with the transmission chamber. The first heating wire is directly fixed in the casing and the first heating wire is positioned between the crucible and the spray nozzle. The lifting mechanism is movably connected to the casing.

### FIELD OF THE INVENTION

The present disclosure relates to the field of manufacturing displays, and more particularly to an evaporation source.

### BACKGROUND OF THE INVENTION

OLED (organic light-emitting diodes) display technology has display methods different from that of traditional LCDs (liquid crystal displays). It does not require a backlight and utilizes an ultra thin organic material coating layer. The organic material emits light when an electric current is passed through it. The existing OLED devices are manufactured using evaporation equipment and vacuum evaporation.

Vacuum evaporation means that the coating material is heated in a high vacuum environment, sublimated, and formed on the substrate. In existing large-size linear evaporation sources, a crucible is received in the evaporation source, the crucible is heated from the outside in the evaporation process, and vapor of the coating material is formed and injected from the injection port.

The existing evaporation equipment is generally divided into two kinds. FIG. 1 is a first evaporation equipment. An evaporation source of an evaporation equipment shown in FIG. 1 is continuously vapor deposited in a high vacuum environment, an organic material 50 is loaded in a crucible 30, the organic material is vaporized through an inner plate 20 and then is injected from a nozzle 10 under the heating of a heating wire 40 to form a film on a substrate. In the actual production process, there is a need for continuous heating for several days. Prolonged heating results in thermal cracking of the organic material, thus affecting performance of the OLED device, resulting in poor production.

FIG. 2 is a second evaporation equipment. An evaporation source of an evaporation equipment shown in FIG. 2 is continuously vapor deposited in a high vacuum environment, an organic material 5 is loaded in a crucible 6, the organic material is vaporized through a transmission chamber 3 and an inner plate 2 and then is injected from a nozzle 1 under the heating of a heating wire 4 to form a film on a substrate. In the actual production process, there is a need for continuous heating for several days. Prolonged heating results in thermal cracking of the organic material, thus affecting performance of the OLED device, resulting in poor production.

In summary, when the existing evaporation equipment performs the vacuum evaporation process, prolonged heating easily results in thermal cracking of the organic material, thus affecting the performance of the OLED device, resulting in poor production.

### SUMMARY OF THE INVENTION

An object of the present disclosure is to provide an evaporation source which prevents an organic material from cracking due to prolonged heating, improves the yield of an OLED device, and improves the performance of the OLED device.

To achieve the above object, a preferred embodiment of the present disclosure provides an evaporation source, which includes:

a casing including a first end, a second end opposite the first end, and a transmission chamber disposed between the first end and the second end;

a crucible configured to receive evaporation material, the evaporation material forming a heating surface on a surface in the crucible when the evaporation material is heated in the crucible, the crucible being disposed in the casing and positioned at the second end, and the crucible being in communication with the transmission chamber;

a spray nozzle configured for injecting vapor formed by evaporating the evaporation material, the spray nozzle being disposed at the first end and in communication with the transmission chamber;

a first heating wire configured for heating the heating surface, the first heating wire directly fixed in the casing and positioned between the crucible and the spray nozzle; and

a lifting mechanism movably connected to the casing, the lifting mechanism being fixed and connected to the crucible, the lifting mechanism controlling the crucible to move using the lifting mechanism movably connected to the casing, so as to vary positions of both the first heating wire and the heating surface and thus varying an evaporation rate generated using the first heating wire to heat the evaporation material.

In a preferred embodiment of the present disclosure, the evaporation source further includes a first detector disposed at a position of the crucible, configured for detecting an evaporation rate at the position of the crucible, the lifting mechanism drives the crucible to move when the first detector detects that the evaporation rate at the position of the crucible is different from a first predetermined evaporation rate.

In a preferred embodiment of the present disclosure, the evaporation source further includes a second detector disposed at a position of the spray nozzle, configured for detecting a vapor injection rate of the spray nozzle, the lifting mechanism drives the crucible to move when the second detector detects that the vapor injection rate of the spray nozzle is different from a second predetermined evaporation rate.

In a preferred embodiment of the present disclosure, the lifting mechanism controls a moving direction of the crucible to be perpendicular to the heating surface.

In a preferred embodiment of the present disclosure, the evaporation source further includes a second heating wire fixed in the crucible for heating the evaporation material.

In a preferred embodiment of the present disclosure, the evaporation source further includes a third heating wire fixed in the transmission chamber for heating vapor in the transmission chamber.

In a preferred embodiment of the present disclosure, the transmission chamber includes a first transmission chamber and a second transmission chamber in communication with each other, the first transmission chamber is near the crucible and is directly in communication with the crucible, the second transmission chamber is near the spray nozzle and is directly in communication with the spray nozzle, a portion of the third heating wire is disposed in the first transmission chamber, and another portion of the third heating wire is disposed in the second transmission chamber.

In a preferred embodiment of the present disclosure, the evaporation source includes an inner plate disposed in the second transmission chamber, and the portion of the third heating wire disposed in the second transmission chamber winds the inner plate.

In a preferred embodiment of the present disclosure, the evaporation source further includes a first detector disposed at a position of the crucible, and is configured for detecting an evaporation rate at the position of the crucible, the lifting mechanism drives the crucible to move when the first detector detects that the evaporation rate at the position of the crucible is different from a predetermined evaporation rate, the casing has a first detecting channel, the first detecting channel is in communication with the first transmission chamber, and the first detector is disposed at a position of the first detecting channel.

In a preferred embodiment of the present disclosure, the first detecting channel is extending outward from the first transmission chamber.

Similarly, to achieve the above object, another preferred embodiment of the present disclosure provides an evaporation source, which includes:

a casing including a first end, a second end opposite the first end, and a transmission chamber disposed between the first end and the second end;

a crucible configured to receive evaporation material, the evaporation material forms a heating surface on a surface in the crucible when the evaporation material is heated in the crucible, the crucible being disposed in the casing and positioned at the second end, and the crucible being in communication with the transmission chamber;

a spray nozzle configured for injecting vapor formed by evaporating the evaporation material, the spray nozzle being disposed at the first end and in communication with the transmission chamber;

a first heating wire configured for heating to the heating surface, the first heating wire disposed in the casing and positioned between the crucible and the spray nozzle; and

a lifting mechanism movably connected to the casing, the lifting mechanism being fixed and connected to the first heating wire, so as to vary both positions of the first heating wire and the heating surface and thus varying evaporation rate generated using the first heating wire to heat the evaporation material.

In a preferred embodiment of the present disclosure, the evaporation source further includes a first detector disposed at a position of the crucible, configured for detecting an evaporation rate at the position of the crucible, the lifting mechanism drives the first heating wire to move when the first detector detects that the evaporation rate at the position of the crucible is different from a first predetermined evaporation rate.

In a preferred embodiment of the present disclosure, the evaporation source further includes a second detector disposed at a position of the spray nozzle, configured for detecting a vapor injection rate of the spray nozzle, the lifting mechanism drives the first heating wire to move when the second detector detects that the vapor injection rate of the spray nozzle is different from a second predetermined evaporation rate.

In a preferred embodiment of the present disclosure, the lifting mechanism controls a moving direction of the first heating wire to be perpendicular to the heating surface.

In a preferred embodiment of the present disclosure, the evaporation source further includes a second heating wire fixed in the crucible for heating the evaporation material.

In a preferred embodiment of the present disclosure, the evaporation source further includes a third heating wire fixed in the transmission chamber for heating vapor in the transmission chamber.

In a preferred embodiment of the present disclosure, the transmission chamber includes a first transmission chamber and a second transmission chamber in communication with each other, the first transmission chamber is near the crucible and is directly in communication with the crucible, the second transmission chamber is near the spray nozzle and is directly in communication with the spray nozzle, a portion of the third heating wire is disposed in the first transmission chamber, and another portion of the third heating wire is disposed in the second transmission chamber.

In a preferred embodiment of the present disclosure, the evaporation source includes an inner plate disposed in the second transmission chamber, and the portion of the third heating wire disposed in the second transmission chamber winds the inner plate.

In a preferred embodiment of the present disclosure, the evaporation source further includes a first detector disposed at a position of the crucible, configured for detecting an evaporation rate at the position of the crucible, the lifting mechanism drives the first heating wire to move when the first detector detects that the evaporation rate at the position of the crucible is different from a predetermined evaporation rate, the casing has a first detecting channel, the first detecting channel is in communication with the first transmission chamber, and the first detector is disposed at a position of the first detecting channel.

In a preferred embodiment of the present disclosure, the first detecting channel is extending outward from the first transmission chamber.

Compared to the existing technology, the present disclosure is configured for heating the heating surface by the first heating wire, the first heating wire is positioned between the crucible and the spray nozzle, heating the evaporation material on the heating surface forms evaporation vapor, the evaporation vapor passes through the crucible and the transmission chamber, and then is injected from the spray nozzle, thus preventing the evaporation material located inside the crucible (the evaporation material located in the crucible and located on the heating surface) from cracking due to prolonged heating.

Moreover, in the present disclosure, the lifting mechanism controls the crucible to move using the lifting mechanism movably connected to the casing, so as to vary positions of both the crucible and the first heating wire and vary positions of both the first heating wire and the heating surface and thus vary an evaporation rate generated using the first heating wire to heat the evaporation material. Specifically, when the evaporation rate is to be increased, the lifting mechanism drives the crucible to move upward (toward the spray nozzle), the first heating wire is fixed in the housing, the distance between the crucible and the first heating wire is reduced, and the distance between the first heating wire and the heating surface is accordingly reduced so that the heating effect of the first heating wire on the heating surface is improved. The first heating wire is gradually advanced into the crucible and the evaporation material through the heating surface, which further increases the heating area of the first heating wire and the evaporation material, thus increasing the evaporation rate of the evaporation material.

When the evaporation rate is to be reduced, the lifting mechanism drives the crucible to move down (moving away from the direction of the spray nozzle), the lifting mechanism controls the distance between the crucible and the first heating wire to be gradually increased and the distance between the first heating wire and the heating surface is accordingly increased so that the heating effect of the first heating wire on the heating surface is reduced, thus reducing the evaporation rate of the evaporation material.

Therefore, the present disclosure controls the crucible to move by the lifting mechanism, changes the distance between the heating surface formed by the evaporation material in the crucible and the first heating wire, controls the heating efficiency of the first heating wire on the heating surface, further controls the evaporation rate of the evaporation material, prevents the evaporation material from cracking due to prolonged heating by the first heating wire, improves the yield of an OLED device, and improves the performance of the OLED device.

For more clearly and easily understanding above content of the present disclosure, the following text will take a preferred embodiment of the present disclosure with reference to the accompanying drawings for detailed description as follows.

### DESCRIPTION OF THE DRAWINGS

The technical solution, as well as beneficial advantages, of the present disclosure will be apparent from the following detailed description of one or more embodiments of the present disclosure, with reference to the attached drawings. In the drawings:

FIG. 1 is a schematic view of an evaporation source in the existing technology.

FIG. 2 is a schematic view of an evaporation source in the existing technology.

FIG. 3 is a schematic view of the evaporation source in a first embodiment of the present disclosure.

FIG. 4 is a schematic view of the evaporation source in a second embodiment of the present disclosure.

FIG. 5 is a schematic view of the evaporation source in a third embodiment of the present disclosure.

FIG. 6 is a schematic view of the evaporation source in a fourth embodiment of the present disclosure.

FIG. 7 is a schematic view of the evaporation source in a fifth embodiment of the present disclosure.

FIG. 8 is a schematic view of the evaporation source in a sixth embodiment of the present disclosure.

FIG. 9 is a schematic view of the evaporation source in a seventh embodiment of the present disclosure.

FIG. 10 is a schematic view of the evaporation source in an eighth embodiment of the present disclosure.

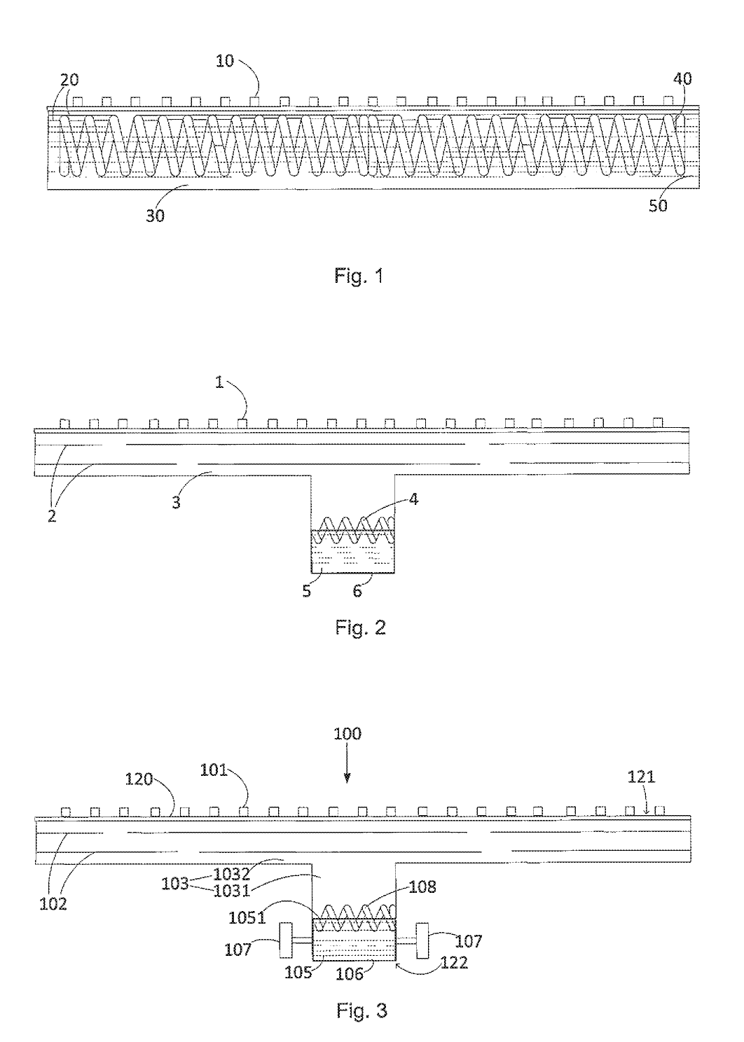

### DETAILED DESCRIPTION OF THE PREFERRED EMBODIMENTS

To further expound the technical solution adopted in the present disclosure and the advantages thereof, a detailed description is given to a preferred embodiment of the present disclosure and the attached drawings. Obviously, the embodiments described herein are only a part of, but not all of, the embodiments of the present disclosure. In view of the embodiments described herein, any other embodiment obtained by the person skilled in the field without offering creative effort is included in a scope claimed by the present disclosure.

The embodiments described herein with reference to the accompanying drawings are explanatory, illustrative, and used to generally understand the present disclosure. Furthermore, directional terms described by the present disclosure, such as center, horizontal, upper, lower, left, right, vertical, horizontal, top, bottom, inner, outer, etc., are only directions or positions by referring to the accompanying drawings, and thus the used terms are used only for the purpose of describing embodiments of the present disclosure and simplifying the description and are not intended to indicate or imply that the devices or elements involved must be in, be configured with, or operate with a particular orientation or position, therefore the present disclosure is not limited thereto. In addition, terms such as “first” and “second” are used herein for purposes of description and are not intended to indicate or imply relative importance or significance. In the description of the present disclosure, “a plurality of” relates to two or more than two. Furthermore, the terms “including” and “having” and any deformations are intended to cover non-exclusive inclusion.

Unless otherwise stated and defined, the terms “mount,” “connected with,” and “connect” should be interpreted broadly. For example, they can mean a fixed connection, or a detachable connection, or an integral connection; they can mean a mechanical connection, or an electrical connection; they can mean a direct connection, or an indirect connection via an intermediate media, or inside communication of two elements. For those of ordinary skills in the art, meanings of the above-mentioned terms in the present disclosure may be understood depending on specific circumstances.

The terms “a,” “an,” and “the” are for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including” when used herein, specify the presence of stated features, integers, steps, operations, elements and/or components, but do not preclude the presence or addition of one or more other features, integers, steps, operations, elements, components and/or groups thereof.

In the drawings, modules with similar structures are labeled with the same reference number.

Referring to FIGS. 3 to 10 and preferred embodiments, the following detailed description of the evaporation source in one or more embodiments of the present disclosure is provided.

Referring now to FIG. 3, a schematic view of the evaporation source in a first embodiment of the present disclosure is illustrated. The evaporation source 100 in a first embodiment of the present disclosure includes a casing 120, an inner plate 102, a crucible 106, a spray nozzle 101, a first heating wire 108, and a lifting mechanism 107.

The casing 120 includes a first end 121, a second end 122 opposite the first end 121, and a transmission chamber 103 disposed between the first end 121 and the second end 122. The transmission chamber 103 is configured to transmit evaporation vapor formed from by heating evaporation material 105. The transmission chamber 103 includes a first transmission chamber 1031 and a second transmission chamber 1032 in communication with each other, the first transmission chamber 1031 is near the crucible 106 and is directly in communication with the crucible 106, the second transmission chamber 1032 is near the spray nozzle 101 and is directly in communication with the spray nozzle 101.

The inner plate 102 is disposed in the second transmission chamber 1032.

The crucible 106 is configured to dispose of the evaporation material 105, the evaporation material 105 forms a heating surface 1051 on a surface in the crucible 106 when the evaporation material 105 is heated in the crucible 106, the crucible 106 is disposed in the casing 120 and is positioned at the second end 122, and the crucible 106 is in communication with the transmission chamber 103.

The spray nozzle 101 is configured for injecting vapor formed by evaporating the evaporation material 105, and the spray nozzle 101 is disposed at the first end 121 and is in communication with the transmission chamber 103. Heating the evaporation material 105 in the crucible forms evaporation vapor, the evaporation vapor passes through the transmission chamber 103 and reaches the spray nozzle 101, and then is injected from the spray nozzle 101.

The first heating wire 108 is configured for heating the heating surface 1051, the first heating wire 108 is directly fixed in the casing 120, and the first heating wire 108 is positioned between the crucible 106 and the spray nozzle 101. The evaporation material 105 disposed in the crucible 106 is heated by the first heating wire 108, the first heating wire 108 is positioned between the crucible 106 and the spray nozzle 101, Heating the evaporation material 105 on the heating surface 1051 forms evaporation vapor, the evaporation vapor passes through the crucible 106 and the transmission chamber 103, and then is injected from the spray nozzle 101, thus preventing the evaporation material 105 located inside the crucible 106 (the evaporation material located in the crucible and located on the heating surface) from cracking due to prolonged heating.

The lifting mechanism 107 is movably connected to the casing 120, the lifting mechanism 107 is fixed and connected to the crucible 106, the lifting mechanism 107 controls the crucible 106 to move using the lifting mechanism 107 movably connected to the casing 120, so as to vary positions of both the first heating wire 105 and the heating surface 1051 and thus vary an evaporation rate generated using the first heating wire 108 to heat the evaporation material 105.

Further, the movable connection of the lifting mechanism 107 and the casing 120 of the first embodiment of the present disclosure can be carried out by means of a slide rail and a chute. For example, the chute is disposed on the casing, and the slide rail to be received in the chute of the casing is disposed on the lifting mechanism, and the slide rail of the lifting mechanism can slide in the chute of the casing to achieve movable connection of the lifting mechanism and the casing.

The casing 120 and the lifting mechanism 107 of the first embodiment of the present disclosure may also be other movable connection means. For example, the casing and the lifting mechanism are movably connected by means of pins and pin holes. Specifically, the pin holes spaced from each other are disposed on the casing, pins for inserting into the pin holes of the casing are disposed on the lifting mechanism, and movable connection between the lifting mechanism and the casing is achieved by adjusting the pins to insert into pin holes in different positions.

For example, the casing and the lifting mechanism use a gear or a gear and a belt for connection. The movable connection between the lifting mechanism and the casing can be achieved by rotation of two or more gears.

The lifting mechanism 107 drives the crucible 106 to move up or down. The lifting mechanism 107 controls a moving direction of the crucible 106 to be perpendicular to the heating surface 1051. It is to be noted that the lifting mechanism 107 controls the crucible 106 to move up or down, the lifting mechanism 107 may be inclined to the heating surface. That is an angle is formed between the moving direction of the crucible and the heating surface.

The first embodiment of the present disclosure controls the movement of the crucible 106 by the lifting mechanism 107 to change the distance between the crucible 106 and the first heating wire 108 while changing the both positions of the first heating wire 108 and the heating surface 1051, thus changing the evaporation rate generated using the first heating wire 108 to heat the evaporation material 105. The first embodiment of the present disclosure not only prevents the evaporation material from cracking due to prolonged heating, but also but also offers convenience to control the evaporation rate, further improves the yield of OLED devices, and improves performance of the OLED devices.

In the first embodiment of the present disclosure, referring to FIG. 3, the detailed process of the evaporation of the evaporation material is as follows.

The evaporation material 105 is disposed in the crucible 106 and the evaporation material located on the heating surface 1051 is heated by the first heating wire 108 so that the evaporation material 105 located on the heating surface 1051 is vaporized to form the evaporation vapor. The evaporation vapor passes through the crucible 106 and the transmission chamber 103 and reaches to the spray nozzle 101, and the evaporation vapor is injected from the spray nozzle 101.

First, the evaporation vapor passes through the crucible 106 and reaches the transmission chamber 103.

Then, the lifting mechanism 107 controls the movement of the crucible 106 according to the rate of the evaporation vapor. The specific movement mode is as follows.

When the evaporation rate is small, or a first predetermined evaporation rate is set in advance, the first predetermined evaporation rate can maintain yield. That is, when the evaporation rate is less than the first predetermined evaporation rate, the evaporation rate is increased in order to maintain the yield.

More specifically, the lifting mechanism 107 drives the crucible 106 to move up, the first heating wire 108 is fixed in the casing 120, the distance between the crucible 106 and the first heating wire 108 is reduced, such as reducing the distance from the top of the crucible to the bottom of the first heating wire, or reducing the distance from the center of the crucible to the center of the first heating wire. It should be noted that the change in the distance between the crucible and the first heating wire of the embodiment of the present disclosure is relative to the same position. The distance between the first heating wire 108 and the heating surface 1051 is reduced, such as reducing the distance from the heating surface to the bottom of the first heating wire or reducing the distance from the heating surface to the center of the first heating wire. It should be noted that the change in the distance between the heating surface and the first heating wire of the embodiment of the present disclosure is relative to the same position. The heating effect of first heating wire 108 on the heating surface 1051 is improved. The first heating wire 108 is gradually advanced into the crucible 106 and the evaporation material 105 through the heating surface 1051, which further increases the heating area of the first heating wire 108 and the evaporation material 105, thus increasing the evaporation rate of the evaporation material to reach the first predetermined evaporation rate.

When the evaporation rate is large, or if the evaporation rate is greater than the first predetermined evaporation rate, it is necessary to reduce the evaporation rate in order to maintain the yield.

More specifically, the lifting mechanism 107 drives the crucible 106 to move down, the lifting mechanism 107 controls the distance between the first heating wire 108 and the crucible 106 to be gradually increased, and the distance between the first heating wire 108 and the heating surface 1051 is accordingly increased so that the heating effect of the first heating wire 108 on the heating surface 1051 is reduced, thus reducing the evaporation rate of the evaporation material to the first predetermined evaporation rate.

It improves the yield of the OLED device and improves the performance of the OLED device.

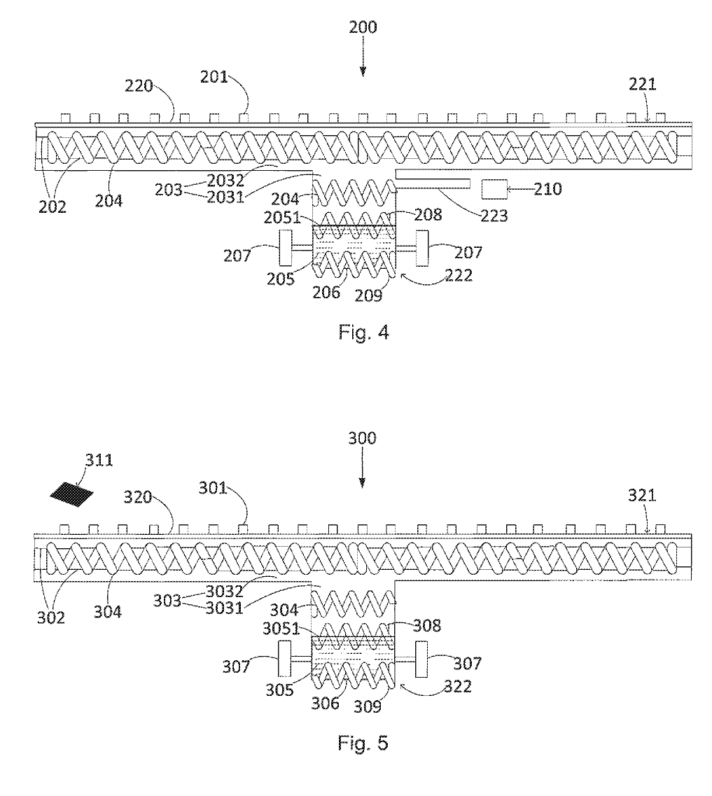

Referring to FIG. 4, a schematic view of the evaporation source in a second embodiment of the present disclosure is illustrated. The evaporation source 200 in a second embodiment of the present disclosure includes a casing 220, an inner plate 202, a crucible 206, a spray nozzle 201, a first heating wire 208, a lifting mechanism 207, and a first detector 210.

The crucible 206 of the second embodiment of the present disclosure has the same structure as the crucible 106 of the first embodiment of the present disclosure. The inner plate 202 of the second embodiment of the present disclosure has the same structure as that of the inner plate 102 of the first embodiment of the present disclosure. The spray nozzle 201 of the second embodiment is the same as the spray nozzle 101 of the first embodiment of the present disclosure. The first heating wire 208 of the second embodiment of the present disclosure has the same structure as the first heating wire 108 of the first embodiment of the present disclosure. The lifting mechanism 207 of the second embodiment is the same as that of the lifting mechanism 107 of the first embodiment of the present disclosure, and it will not be described again.

The second embodiment of the present disclosure is based on the improvement of the first embodiment, and the second embodiment of the present disclosure is different from the first embodiment in that the second embodiment of the present disclosure further includes the first detector 210.

Further, the second embodiment of the present disclosure is different from the first embodiment in that the casing 220 of the second embodiment of the present disclosure is provided with a first detecting channel 223 and a first end 221 and a second end 222 of the casing 220, a first transmission chamber 2031 and a second transmission chamber 2032 of the transmission chamber 203 of the second embodiment of the present disclosure are the same in structure and effect as the first end 121 and the second end 122 of the casing 120, the first transmission chamber 1031 and the second transmission chamber 1032 of the transmission chamber 103 of the first embodiment of the present disclosure, and it will not be described again.

The first detector 210 is disposed on the casing 220 at the position of the crucible 206 for detecting an evaporation rate at the position of the crucible (defined herein as a first evaporation rate). The lifting mechanism 207 drives the crucible 206 to move when the first detector 210 detects that the evaporation rate at the position of the crucible 206 is different from the predetermined evaporation rate.

Specifically, the first detector 210 is disposed at the position of the first detecting channel 223, the first detecting channel 223 is in communication with the first transmission chamber 2031, and the first detecting channel 223 is extending outward from the first transmission chamber 2031.

The second embodiment of the present disclosure compares the first evaporation rate detected by the first detector 210 with the first predetermined evaporation rate, the evaporation rate is increased in order to maintain the yield when the first evaporation rate detected by the first detector 210 is less than the first predetermined evaporation rate. More specifically, the lifting mechanism 207 drives the crucible 206 to move up, the first heating wire 208 is fixed in the casing 220, the distance between the crucible 206 and the first heating wire 208 is reduced, such as reducing the distance from the top of the crucible 206 to the bottom of the first heating wire 208, or reducing the distance from the center of the crucible 206 to the center of the first heating wire 208. It should be noted that the change in the distance between the crucible and the first heating wire of the embodiment of the present disclosure is relative to the same position. The distance between the first heating wire 208 and the heating surface 2051 is reduced, such as reducing the distance from the heating surface 2051 to the bottom of the first heating wire 208 or reducing the distance from the heating surface 2051 to the center of the first heating wire 208. It should be noted that the change in the distance between the heating surface and the first heating wire of the embodiment of the present disclosure is relative to the same position. The heating effect of first heating wire 208 on the heating surface 2051 is improved. The first heating wire 208 is gradually advanced into the crucible 206 and the evaporation material 205 through the heating surface 2051, which further increases the heating area of the first heating wire 208 and the evaporation material 205, thus increasing the evaporation rate of the evaporation material 205 to reach the first predetermined evaporation rate.

When the first evaporation rate detected by the first detector 210 is greater than the first predetermined evaporation rate, it is necessary to reduce the evaporation rate in order to maintain the yield. More specifically, the lifting mechanism 207 drives the crucible 206 to move down, the lifting mechanism 207 controls the distance between the first heating wire 208 and the crucible 206 to be gradually increased, and the distance between the first heating wire 208 and the heating surface 2051 is accordingly increased so that the heating effect of the first heating wire 208 on the heating surface 2051 is reduced, thus reducing the evaporation rate of the evaporation material to the first predetermined evaporation rate.

The first predetermined evaporation rate is the predetermined evaporation rate, which can be changed according to the specific requirements.

It is understood that the second embodiment of the present disclosure detects the evaporation rate at the position of the crucible 206 by the first detector 210 and feeds back to the lifting mechanism 207 in a timely manner, so that the lifting mechanism 207 makes adjustments to control the crucible 206 to make the corresponding movement, and thus controls the evaporation rate of the evaporation material by the first heating wire 208 in a more timely manner to further improve the yield of the OLED device, and to improve the performance of the OLED device.

In the evaporation source of the second embodiment of the present disclosure, the evaporation source 200 further includes a second heating wire 209 fixed in the crucible 206 for heating the evaporation material 205. When the evaporation material 205 is disposed in the crucible 206, the evaporation material 205 covers the second heating wire 209, and the second heating wire 209 is positioned on the heating surface 2051. The second heating wire 209 is used to preheat the evaporation material 205 in the crucible 206.

Specifically, the first heating wire 208 heats the evaporation material 205 disposed on the heating surface 2051 so that the evaporation material 205 disposed on the heating surface 2051 is heated and vaporized. The second heating wire 209 preheats the evaporation material 205 in the crucible 206. When the evaporation material 205 disposed on the heating surface 2051 is gradually vaporized and the lifting mechanism 207 drives the crucible 206 to move up, the first heating wire 208 remains heating the evaporation material 205 disposed on the heating surface 2051. The second heating wire 209 preheats the evaporation material 205 in the crucible 206 so that the first heating wire 208 heats the heating surface 2051 to vaporize the evaporation material 205.

In the second embodiment of the present disclosure, since the second heating wire 209 is fixed in the crucible 206 and the lifting mechanism 207 controls the movement of the crucible 206, the second heating wire 209 moves in accordance with the movement of the crucible 206.

The heating temperature of the second heating wire 209 may be set less than the heating temperature of the first heating wire 208 so that the heating effect of the second heating wire 209 preheating the evaporation material 205 in the crucible 206 is improved, thereby preventing the evaporation material 205 disposed in the crucible 206 from cracking due to prolonged heating. It is noted that the second heating wire 209 may preheat the evaporation material 205 in the crucible 206 continuously, or may preheat the evaporation material 205 in the crucible 206 in intervals.

In the second embodiment of the present disclosure, the evaporation source further includes a third heating wire 204 fixed in the transmission chamber 203 for heating the vapor in the transmission chamber 203. The evaporation vapor of the evaporation material 205 is heated secondly by the third heating wire 204 to increase the saturated vapor pressure inside the evaporation source 200 so that the evaporation vapor formed by the evaporation material 205 is injected from the spray nozzle 201 more uniformly, the temperature of the evaporation vapor is increased, it is difficult to form crystals in the spray nozzle 201, and the clogging problem is avoided.

Specifically, a portion of the third heating wire 204 is disposed in the first transmission chamber 2031 and another portion of the third heating wire 204 is disposed in the second transmission chamber 2032. The portion of the third heating wire 204 disposed in the second transmission chamber 2032 winds the inner plate 202.

Referring to FIG. 4, the detailed process of the evaporation of the evaporation material in the second embodiment of the present disclosure is carried out by mounting the first detector 210 at the position of the crucible 206, detecting the evaporation rate at the position of the crucible 206, and driving the lifting mechanism 207 to move the crucible 206 according to the detecting result, thus controlling the evaporation rate. The detailed process is as follows.

The evaporation material is disposed in the crucible 206 and the evaporation material located on the heating surface 2051 is heated by the first heating wire 208 so that the evaporation material located on the heating surface 2051 is vaporized to form the evaporation vapor. The evaporation vapor passes through the crucible 206, the transmission chamber 203, and the first detecting channel 223, and reaches the spray nozzle 201, and the evaporation vapor is injected from the spray nozzle 201.

First, the evaporation vapor passes through the crucible 206 and reaches the transmission chamber 203. The evaporation vapor is heated secondly by the third heating wire 204 of the transmission chamber 203 to increase the saturated vapor pressure inside the evaporation source 200 so that the evaporation vapor formed by the evaporation material is injected from the spray nozzle 201 more uniformly, the temperature of the evaporation vapor is increased, it is difficult to form crystals in the spray nozzle 201, and the clogging problem is avoided.

Then, the evaporation vapor passes through the first detecting channel 223, and the first detector 210 disposed at the first detecting channel 223 detects the evaporation rate of the evaporation vapor and compares with the first predetermined evaporation rate. The lifting mechanism 207 drives the crucible 206 to move according to the comparison result. The specific movement mode is as follows.

The evaporation rate is increased in order to maintain the yield when the first evaporation rate detected by the first detector 210 is less than the first predetermined evaporation rate. More specifically, the lifting mechanism 207 drives the crucible 206 to move up, the first heating wire 208 is fixed in the casing 220, the distance between the crucible 206 and the first heating wire 208 is reduced, such that the heating effect of first heating wire 208 on the heating surface 2051 is improved. The first heating wire 208 is gradually advanced into the crucible 206 and the evaporation material through the heating surface 2051, which further increases the heating area of the first heating wire 208 and the evaporation material 205, thus increasing the evaporation rate of the evaporation material to reach the first predetermined evaporation rate.

When the first evaporation rate detected by the first detector 210 is greater than the first predetermined evaporation rate, it is necessary to reduce the evaporation rate in order to maintain the yield. More specifically, the lifting mechanism 207 drives the crucible 206 to move down, the lifting mechanism 207 controls the distance between the first heating wire 208 and the crucible 206 to be gradually increased, and the distance between the first heating wire 208 and the heating surface 2051 is accordingly increased so that the heating effect of the first heating wire 208 on the heating surface 2051 is reduced, thus reducing the evaporation rate of the evaporation material to the first predetermined evaporation rate.

Then, the first heating wire 208 heats the heating surface 2051 continuously so that the evaporation material disposed on the heating surface 2051 is gradually vaporized. The second heating wire 209 preheats the evaporation material in the crucible 206. The lifting mechanism 207 drives the crucible 206 to move up, the first heating wire 208 remains heating the evaporation material disposed on the heating surface 2051. The second heating wire 209 preheats the evaporation material in the crucible 206 so that the first heating wire 208 heats the heating surface 2051 to vaporize the evaporation material 205, and the evaporation rate of the evaporation material is ensured.

Therefore, the second embodiment of the present disclosure feeds back the detecting result of the first detector 210 to the lifting mechanism 207 in a timely manner, the lifting mechanism 207 controls the movement of the crucible 206 to change the distance between the heating surface 2051 formed by the evaporation material in the crucible 206 and the first heating wire 208 more timely and precisely, so as to control the heating efficiency of the first heating wire 208 on the heating surface 2051 more timely and precisely, further control the evaporation rate of the evaporation material more timely and precisely, prevent the evaporation material from cracking due to prolonged heating by the first heating wire 208, improve the yield of an OLED device, and improve the performance of the OLED device.

Referring to FIG. 5, a schematic view of the evaporation source in a third embodiment of the present disclosure is illustrated. The evaporation source 300 in a third embodiment of the present disclosure includes a casing 320, an inner plate 302, a crucible 306, a spray nozzle 301, a first heating wire 308, a lifting mechanism 307, and a second detector 311.

The third embodiment of the present disclosure is based on the improvement of the second embodiment, and the third embodiment of the present disclosure is different from the second embodiment in that the second detector 311 of the third embodiment of the present disclosure is disposed at the position of the spray nozzle 301, the first detector of the second embodiment of the present disclosure is disposed at the position of the crucible. The third embodiment of the present disclosure uses the second detector 311 instead of the first detector.

The inner plate 302, the crucible 306, the spray nozzle 301, the first heating wire 308, the lifting mechanism 307, the second heating wire 309, and the third heating wire 304 of the third embodiment of the present disclosure respectively have the same structure and effect as the inner plate 202, the crucible 206, the spray nozzle 201, the first heating wire 208, the lifting mechanism 207, the second heating wire 209, and the third heating wire 204 of the second embodiment of the present disclosure, and it will not be described again.

The casing 320 of the third embodiment of the present disclosure is different from the casing 220 of the second embodiment of the present disclosure in that the casing 320 of the third embodiment of the present disclosure does not dispose the first detecting channel. The first end 321 and the second end 322 of the casing 320, the first transmission chamber 3031 and the second transmission chamber 3032 of the transmission chamber 303 of the third embodiment of the present disclosure respectively have the same structure and effect as the first end 221 and the second end 222 of the casing, and the first transmission chamber 2031 and the second transmission chamber 2032 of the transmission chamber 203 of the second embodiment of the present disclosure, and it will not be described again.

When the evaporation material 305 is heated in the crucible 306, the evaporation material 305 forms a heating surface 3051 in the crucible 306.

Specifically, the second detector 311 is disposed at the position of the spray nozzle 301 for detecting the rate of the spray nozzle 301 injecting the vapor (defined herein as a second evaporation rate). The lifting mechanism 307 drives the crucible 306 to move when the second detector 311 detects that the second evaporation rate of the spray nozzle 301 injecting the vapor is different from the second predetermined evaporation rate.

The third embodiment of the present disclosure compares the second evaporation rate detected by the second detector 311 with the second predetermined evaporation rate, the evaporation rate is increased in order to maintain the yield when the second evaporation rate detected by the second detector 311 is less than the second predetermined evaporation rate. More specifically, the lifting mechanism 307 drives the crucible 306 to move up, the first heating wire 308 is fixed in the casing 320, the distance between the crucible 306 and the first heating wire 308 is reduced, such as reducing the distance from the top of the crucible 306 to the bottom of the first heating wire 308, or reducing the distance from the center of the crucible 306 to the center of the first heating wire 308. It should be noted that the change in the distance between the crucible and the first heating wire of the embodiment of the present disclosure is relative to the same position. The distance between the first heating wire 308 and the heating surface 3051 is reduced, such as reducing the distance from the heating surface 3051 to the bottom of the first heating wire 308 or reducing the distance from the heating surface 3051 to the center of the first heating wire 308. It should be noted that the change in the distance between the heating surface and the first heating wire of the embodiment of the present disclosure is relative to the same position. The heating effect of first heating wire 308 on the heating surface 3051 is improved. The first heating wire 308 is gradually advanced into the crucible 306 and the evaporation material 305 through the heating surface 3051, which further increases the heating area of the first heating wire 308 and the evaporation material 305, thus increasing the evaporation rate of the evaporation material 305 to reach the second predetermined evaporation rate.

When the second evaporation rate detected by the second detector 311 is greater than the second predetermined evaporation rate, it is necessary to reduce the evaporation rate in order to maintain the yield. More specifically, the lifting mechanism 307 drives the crucible 306 to move down, the lifting mechanism 307 controls the distance between the first heating wire 308 and the crucible 306 to be gradually increased, and the distance between the first heating wire 308 and the heating surface 3051 is accordingly increased so that the heating effect of the first heating wire 308 on the heating surface 3051 is reduced, thus reducing the evaporation rate of the evaporation material to the second predetermined evaporation rate.

The second predetermined evaporation rate is the predetermined evaporation rate, which can be changed according to the specific requirements.

The third embodiment of the present disclosure feeds back the detecting result of the second detector 311 to the lifting mechanism 307 in a timely manner, the lifting mechanism 307 controls the movement of the crucible 306 to change the distance between the heating surface 3051 formed by the evaporation material in the crucible 306 and the first heating wire 308 more timely and precisely, so as to control the heating efficiency of the first heating wire 308 on the heating surface 3051 more timely and precisely, further control the evaporation rate of the evaporation material more timely and precisely, prevent the evaporation material from cracking due to prolonged heating by the first heating wire 308, improve the yield of an OLED device, and improve the performance of the OLED device.

In addition, since the second detector 311 is disposed at the position of the spray nozzle 301, the position of the spray nozzle 301 is closer to the substrate, and the rate of the evaporation vapor at the position of the spray nozzle 301 can be controlled more timely and accurately so that the evaporation vapor forming the film on the substrate is more uniform, and the heating effect is improved.

Referring to FIG. 5, the detailed process of the evaporation of the evaporation material in the third embodiment of the present disclosure is different from the detailed process of the evaporation of the evaporation material in the second embodiment of the present disclosure in that the evaporation source of the third embodiment of the present disclosure detects the evaporation rate by the second detector disposed at the position of the spray nozzle, see the second embodiment of the present disclosure for details, it will not be described again.

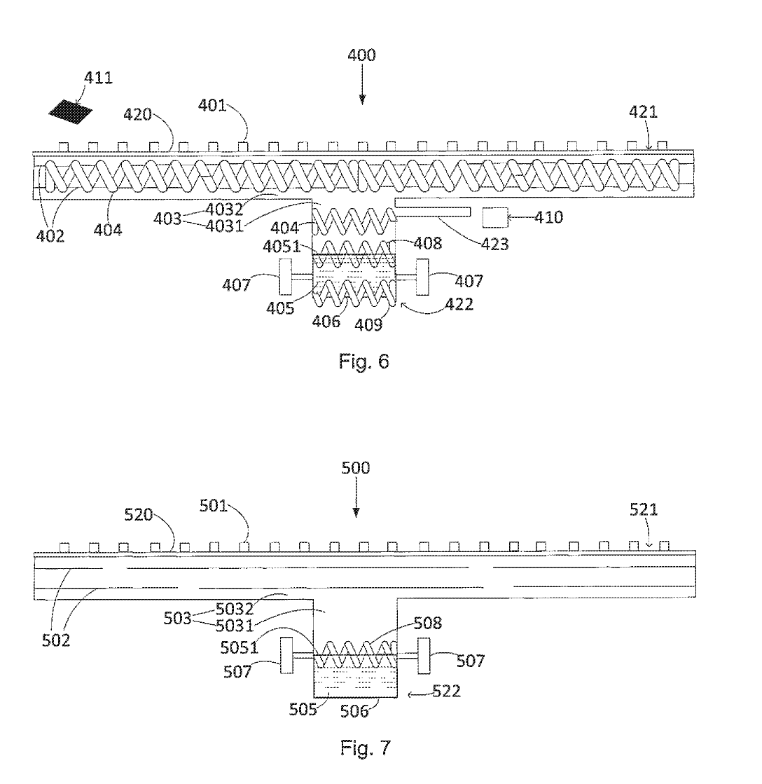

Refer to FIG. 6, which is a schematic view of the evaporation source in a fourth embodiment of the present disclosure. The evaporation source 400 in a fourth embodiment of the present disclosure includes a casing 420, an inner plate 402, a crucible 406, a spray nozzle 401, a first heating wire 408, a lifting mechanism 407, a first detector 410, and a second detector 411.

The fourth embodiment of the present disclosure is based on the improvement of the second embodiment and the third embodiment of the present disclosure, and the fourth embodiment of the present disclosure is different from the second embodiment in that the second detector 411 of the fourth embodiment of the present disclosure is disposed at the position of the spray nozzle 401 and the second embodiment of the present disclosure does not dispose the second detector.

The inner plate 402, the crucible 406, the spray nozzle 401, the first heating wire 408, the lifting mechanism 407, the second heating wire 409, the third heating wire 404, and the first detector 410 of the fourth embodiment of the present disclosure respectively have the same structure and effect as the inner plate 202, the crucible 206, the spray nozzle 201, the first heating wire 208, the lifting mechanism 207, the second heating wire 209, the third heating wire 204, and the first detector 210 of the second embodiment of the present disclosure, and it will not be described again.

The first end 421 and the second end 422 of the casing 420, and the first transmission chamber 4031 and the second transmission chamber 4032 of the transmission chamber 403 of the fourth embodiment of the present disclosure respectively have the same structure and effect as the first end 221 and the second end 222 of the casing, and the first transmission chamber 2031 and the second transmission chamber 2032 of the transmission chamber 203 of the second embodiment of the present disclosure, and it will not be described again.

When the evaporation material 405 is heated in the crucible 406, the evaporation material 405 forms a heating surface 4051 in the crucible 406.

In the fourth embodiment of the present disclosure, when the first evaporation rate detected by the first detector 410 is less than the first predetermined evaporation rate and the second evaporation rate detected by the second detector 411 is less than the second predetermined evaporation rate, the lifting mechanism 407 drives the crucible 406 to move up, such that the evaporation rate is increased in order to maintain the yield.

When the first evaporation rate detected by the first detector 410 is greater than the first predetermined evaporation rate and the second evaporation rate detected by the second detector 411 is greater than the second predetermined evaporation rate, the lifting mechanism 407 drives the crucible 406 to move down to reduce the evaporation rate.

When a detecting result of the first detector 410 is different from a detecting result of the second detector 411, the detecting result of the second detector 411 prevails.

The second detector 411 is disposed at the position of the spray nozzle, so that the evaporation vapor injecting from the spray nozzle can be uniform and thus be prevented from impacting the OLED production and yield.

Further, when the detecting results of the first detector 410 and the second detector 411 are different, an alarm having a different detecting result of the first detector 410 and the second detector 411 is issued and displayed so that a worker can perform site inspection and maintenance.

The above is only a method in which the first detector 410 and the second detector 411 work together in the fourth embodiment of the present disclosure. In the fourth embodiment of the present disclosure, the first detector 410 and the second detector 411 may use other working methods, for example, when a detecting result of the first detector 410 is different from a detecting result of the second detector 411, the detecting result of the first detector 410 prevails.

The specific detecting result is different in that the first evaporation rate detected by the first detector 410 is less than the first predetermined evaporation rate and the second evaporation rate detected by the second detector 411 is greater than the second predetermined evaporation rate, or the first evaporation rate detected by the device 410 is greater than the first predetermined evaporation rate and the second evaporation rate detected by the second detector 411 is less than the second predetermined evaporation rate.

Similarly, the fourth embodiment of the present disclosure feeds back the detecting results of the first detector 410 and the second detector 411 to the lifting mechanism 407 in a timely manner, the lifting mechanism 407 controls the movement of the crucible 406 to change the distance between the heating surface 4051 formed by the evaporation material in the crucible 406 and the first heating wire 408 more timely and precisely, so as to control the heating efficiency of the first heating wire 408 on the heating surface 4051 more timely and precisely, further control the evaporation rate of the evaporation material more timely and precisely, prevent the evaporation material 405 from cracking due to prolonged heating by the first heating wire 408, improve the yield of an OLED device, and improve the performance of the OLED device.

In addition, since the first detector 410 is disposed at the position of the crucible 406 closer to the evaporation material 405, and the rate of the evaporation vapor at the position of the crucible 406 can be controlled more timely and accurately so that the evaporation vapor formed by the evaporation material 405 is more uniform, the heating effect is improved.

In addition, since the second detector 411 is disposed at the position of the spray nozzle 401, the position of the spray nozzle 401 is closer to the substrate, and the rate of the evaporation vapor at the position of the spray nozzle 401 can be controlled more timely and accurately so that the evaporation vapor forming the film on the substrate is more uniform, and the heating effect is improved.

The detailed process of the evaporation of the evaporation material in the fourth embodiment of the present disclosure is different from the detailed process of the evaporation of the evaporation material in the second embodiment of the present disclosure in that the evaporation source of the fourth embodiment of the present disclosure detects the evaporation rate by both the second detector disposed at the position of the spray nozzle and the first detector disposed at the position of the first detecting channel, the heating effect is improved; see the second embodiment of the present disclosure for details, it will not be described again.

Refer to FIG. 7, which is a schematic view of the evaporation source in a fifth embodiment of the present disclosure. The evaporation source 500 in a fifth embodiment of the present disclosure includes a casing 520, an inner plate 502, a crucible 506, a spray nozzle 501, a first heating wire 508, and a lifting mechanism 507.

The casing 520 includes a first end 521, a second end 522 opposite the first end 521, and a transmission chamber 503 disposed between the first end 521 and the second end 522. The transmission chamber 503 is configured to transmit evaporation vapor formed from by heating evaporation material 505. The transmission chamber 503 includes a first transmission chamber 5031 and a second transmission chamber 5032 in communication with each other, the first transmission chamber 5031 is near the crucible 506 and is directly in communication with the crucible 506, the second transmission chamber 5032 is near the spray nozzle 501 and is directly in communication with the spray nozzle 501.

The inner plate 502 is disposed in the second transmission chamber 5032.

The crucible 506 is configured to dispose the evaporation material 505, the evaporation material 505 forms a heating surface 5051 on a surface in the crucible 506 when the evaporation material 505 is heated in the crucible 506, the crucible 506 is disposed in the casing 520 and is positioned at the second end 522, and the crucible 506 is in communication with the transmission chamber 503.

The spray nozzle 501 is configured for injecting vapor formed by evaporating the evaporation material 505, the spray nozzle 501 is disposed at the first end 521 and is in communication with the transmission chamber 503. Heating the evaporation material 505 in the crucible forms evaporation vapor, the evaporation vapor passes through the transmission chamber 503 and reaches the spray nozzle 501, and then is injected from the spray nozzle 501.

The first heating wire 508 is configured for heating the heating surface 5051, the first heating wire 508 is directly fixed in the casing 520, and the first heating wire 508 is positioned between the crucible 506 and the spray nozzle 501. The evaporation material 505 disposed in the crucible 506 is heated by the first heating wire 508, the first heating wire 508 is positioned between the crucible 506 and the spray nozzle 501, Heating the evaporation material 505 on the heating surface 5051 forms evaporation vapor, the evaporation vapor passes through the crucible 506 and the transmission chamber 503, and then is injected from the spray nozzle 501, thus preventing the evaporation material 505 located inside the crucible 506 (the evaporation material located in the crucible and located on the heating surface) from cracking due to prolonged heating.

The lifting mechanism 507 is movably connected to the casing 520, the lifting mechanism 507 is fixed and connected to the crucible 506, the lifting mechanism 507 controls the first heating wire 508 to move using the lifting mechanism 507 movably connected to the casing 520, so as to vary both positions of the first heating wire 505 and the heating surface 5051 and thus vary an evaporation rate generated using the first heating wire 508 to heat the evaporation material 505.

Further, the movable connection of the lifting mechanism 507 and the casing 520 of the preferred embodiment of the present disclosure can be carried out by means of a slide rail and a chute, for example, the chute is disposed on the casing, and the slide rail to be received in the chute of the casing is disposed on the lifting mechanism, and the slide rail of the lifting mechanism can slide in the chute of the casing to achieve the movable connection of the lifting mechanism and the casing.

The casing 520 and the lifting mechanism 507 of the fifth embodiment of the present disclosure may also be other movable connection means, for example, the casing and the lifting mechanism are movably connected by means of pins and pin holes. Specifically, the pin holes spaced from each other are disposed on the casing, pins for inserting into the pin holes of the casing are disposed on the lifting mechanism, a movable connection between the lifting mechanism and the casing is achieved by adjusting the pins to insert into pin holes in different positions.

For example, the casing and the lifting mechanism use a gear or a gear and a belt for connection. The movable connection between the lifting mechanism and the casing can be achieved by the rotation of two or more gears.

The lifting mechanism 507 drives the first heating wire 508 to move up or down. The lifting mechanism 507 controls a moving direction of the first heating wire 508 to be perpendicular to the heating surface 5051. It is to be noted that the lifting mechanism 507 controls the first heating wire 508 to move up or down, the lifting mechanism 507 may be inclined to the heating surface, that is an angle is formed between the moving direction of the crucible and the heating surface.

The fifth embodiment of the present disclosure controls the movement of the first heating wire 508 by the lifting mechanism 507 to change the distance between the crucible 506 and the first heating wire 508 while changing the positions of both the first heating wire 508 and the heating surface 5051, thus changing the evaporation rate generated using the first heating wire 508 to heat the evaporation material 505. The fifth embodiment of the present disclosure not only prevents the evaporation material from cracking due to prolonged heating, but also but also offers convenience to control the evaporation rate, further improves the yield of an OLED device, and improves the performance of the OLED device.

In the fifth embodiment of the present disclosure, the detailed process of the evaporation of the evaporation material is as follows.

The evaporation material 505 is disposed in the crucible 506 and the evaporation material located on the heating surface 5051 is heated by the first heating wire 508 so that heating the evaporation material 505 located on the heating surface 5051 forms the evaporation vapor. The evaporation vapor passes through the crucible 506 and the transmission chamber 503 and reaches to the spray nozzle 501, and the evaporation vapor is injected from the spray nozzle 501.

First, the evaporation vapor passes through the crucible 506 and reaches the transmission chamber 503.

Then, the lifting mechanism 507 controls the movement of the crucible 506 according to the rate of the evaporation vapor. The specific movement mode is as follows.

When the evaporation rate is small, or a first predetermined evaporation rate is set in advance, the first predetermined evaporation rate can maintain yield. That is, when the evaporation rate is less than the first predetermined evaporation rate, the evaporation rate is increased in order to maintain the yield.

More specifically, the lifting mechanism 507 drives the crucible 506 to move up, the first heating wire 508 is fixed in the casing 520, the distance between the crucible 506 and the first heating wire 508 is reduced, such as reducing the distance from the top of the crucible to the bottom of the first heating wire, or reducing the distance from the center of the crucible to the center of the first heating wire. It should be noted that the change in the distance between the crucible and the first heating wire of the embodiment of the present disclosure is relative to the same position. The distance between the first heating wire 508 and the heating surface 5051 is reduced, such as reducing the distance from the heating surface to the bottom of the first heating wire or reducing the distance from the heating surface to the center of the first heating wire. It should be noted that the change in the distance between the heating surface and the first heating wire of the embodiment of the present disclosure is relative to the same position. The heating effect of first heating wire 508 on the heating surface 5051 is improved. The first heating wire 508 is gradually advanced into the crucible 506 and the evaporation material 505 through the heating surface 5051, which further increases the heating area of the first heating wire 508 and the evaporation material 505, thus increasing the evaporation rate of the evaporation material to reach the first predetermined evaporation rate.

When the evaporation rate is large, or if the evaporation rate is greater than the first predetermined evaporation rate, it is necessary to reduce the evaporation rate in order to maintain the yield.

More specifically, the lifting mechanism 507 drives the crucible 506 to move down, the lifting mechanism 507 controls the distance between the first heating wire 508 and the crucible 506 to be gradually increased, and the distance between the first heating wire 508 and the heating surface 5051 is accordingly increased so that the heating effect of the first heating wire 508 on the heating surface 5051 is reduced, thus reducing the evaporation rate of the evaporation material to the first predetermined evaporation rate.

It improves the yield of the OLED device and improves the performance of the OLED device.

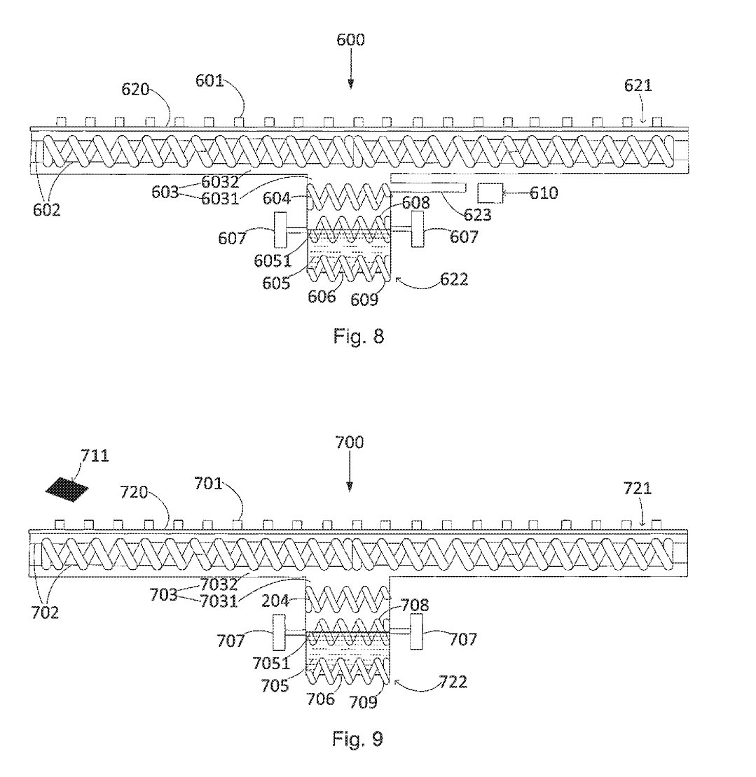

Refer to FIG. 8, which is a schematic view of the evaporation source in a sixth embodiment of the present disclosure. The evaporation source 600 in a sixth embodiment of the present disclosure includes a casing 620, an inner plate 602, a crucible 606, a spray nozzle 601, a first heating wire 608, a lifting mechanism 607, and a first detector 610.

The crucible 606 of the sixth embodiment of the present disclosure has the same structure as the crucible 506 of the fifth embodiment of the present disclosure. The inner plate 602 of the sixth embodiment of the present disclosure has the same structure as that of the inner plate 502 of the fifth embodiment of the present disclosure. The spray nozzle 601 of the sixth embodiment is the same as the spray nozzle 501 of the fifth embodiment of the present disclosure. The first heating wire 608 of the sixth embodiment of the present disclosure has the same structure as the first heating wire 508 of the fifth embodiment of the present disclosure. The lifting mechanism 607 of the sixth embodiment is the same as that of the lifting mechanism 507 of the fifth embodiment of the present disclosure, and it will not be described again.

The sixth embodiment of the present disclosure is based on the improvement of the fifth embodiment, and the sixth embodiment of the present disclosure is different from the fifth embodiment in that the sixth embodiment of the present disclosure further includes the first detector 610.

Further, the sixth embodiment of the present disclosure is different from the fifth embodiment in that the casing 620 of the sixth embodiment of the present disclosure is provided with a first detecting channel 623 and a first end 621 and a second end 622 of the casing 620, a first transmission chamber 6031 and a second transmission chamber 6032 of the transmission chamber 603 of the second embodiment of the present disclosure are the same in structure and effect as the first end 521 and the second end 522 of the casing 520, the first transmission chamber 5031 and the second transmission chamber 5032 of the transmission chamber 503 of the fifth embodiment of the present disclosure, and it will not be described again.

The first detector 610 is disposed on the casing 620 at the position of the crucible 606 for detecting an evaporation rate at the position of the crucible (defined herein as a first evaporation rate). The lifting mechanism 607 drives the first heating wire 608 to move when the first detector 610 detects the evaporation rate at the position of the crucible 606 different from the predetermined evaporation rate.

Specifically, the first detector 610 is disposed at the position of the first detecting channel 623, the first detecting channel 623 is in communication with the first transmission chamber 6031, and the first detecting channel 623 is extending outward from the first transmission chamber 6031.

The sixth embodiment of the present disclosure compares the first evaporation rate detected by the first detector 610 with the first predetermined evaporation rate, the evaporation rate is increased in order to maintain the yield when the first evaporation rate detected by the first detector 610 is less than the first predetermined evaporation rate. More specifically, the lifting mechanism 607 drives the first heating wire 608 to move down, the distance between the crucible 606 and the first heating wire 608 is reduced, such as reducing the distance from the top of the crucible 606 to the bottom of the first heating wire 608, or reducing the distance from the center of the crucible 606 to the center of the first heating wire 608. It should be noted that the change in the distance between the crucible and the first heating wire of the embodiment of the present disclosure is relative to the same position. The distance between the first heating wire 608 and the heating surface 6051 is reduced, such as reducing the distance from the heating surface 6051 to the bottom of the first heating wire 608 or reducing the distance from the heating surface 6051 to the center of the first heating wire 608. It should be noted that the change in the distance between the heating surface and the first heating wire of the embodiment of the present disclosure is relative to the same position. The heating effect of first heating wire 608 on the heating surface 6051 is improved. The first heating wire 608 is gradually advanced into the crucible 606 and the evaporation material 605 through the heating surface 6051, which further increases the heating area of the first heating wire 608 and the evaporation material 605, thus increasing the evaporation rate of the evaporation material 605 to reach the first predetermined evaporation rate.

When the first evaporation rate detected by the first detector 610 is greater than the first predetermined evaporation rate, it is necessary to reduce the evaporation rate in order to maintain the yield. More specifically, the lifting mechanism 607 drives the first heating wire 608 to move up, the lifting mechanism 607 controls the distance between the first heating wire 608 and the crucible 606 to be gradually increased, and the distance between the first heating wire 608 and the heating surface 6051 is accordingly increased so that the heating effect of the first heating wire 608 on the heating surface 6051 is reduced, thus reducing the evaporation rate of the evaporation material to the first predetermined evaporation rate.

The first predetermined evaporation rate is the predetermined evaporation rate, which can be changed according to the specific requirements.

It is understood that the second embodiment of the present disclosure detects the evaporation rate at the position of the crucible 606 by the first detector 610 and feeds back to the lifting mechanism 607 in a timely manner, so that the lifting mechanism 607 makes adjustments to control the crucible 606 to make the corresponding movement, and thus controlling the evaporation rate of the evaporation material by the first heating wire 608 in a more timely manner to further improve the yield of the OLED device, and to improve the performance of the OLED device.

In the evaporation source of the second embodiment of the present disclosure, the evaporation source 600 further includes a second heating wire 609 fixed in the crucible 606 for heating the evaporation material 605. When the evaporation material 605 is disposed in the crucible 606, the evaporation material 605 covers the second heating wire 609, and the second heating wire 609 is positioned on the heating surface 6051. The second heating wire 609 is used to preheat the evaporation material 605 in the crucible 606.

Specifically, the first heating wire 608 heats the evaporation material 605 disposed on the heating surface 6051 so that the evaporation material 605 disposed on the heating surface 6051 is vaporized. The second heating wire 609 preheats the evaporation material 605 in the crucible 606. When the evaporation material 605 disposed on the heating surface 6051 is gradually vaporized and the lifting mechanism 607 drives the crucible 606 to move up, the first heating wire 608 remains heating the evaporation material 605 disposed on the heating surface 6051. Since the second heating wire 609 preheats the evaporation material 605 in the crucible 606 so that the first heating wire 608 heats the heating surface 6051 to vaporize the evaporation material 605.

In the sixth embodiment of the present disclosure, since the second heating wire 609 is fixed in the crucible 606 and the lifting mechanism 607 controls the movement of the crucible 606, the second heating wire 609 moves in accordance with the movement of the crucible 606.

The heating temperature of the second heating wire 609 may be set less than the heating temperature of the first heating wire 608 so that the heating effect of the second heating wire 609 preheating the evaporation material 605 in the crucible 606 is improved, thus preventing the evaporation material 605 disposed in the crucible 606 from cracking due to prolonged heating. It is noted that the second heating wire 609 may preheat the evaporation material 605 in the crucible 606 continuously, or may preheat the evaporation material 605 in the crucible 606 in intervals.

In the sixth embodiment of the present disclosure, the evaporation source further includes a third heating wire 604 fixed in the transmission chamber 603 for heating the vapor in the transmission chamber 603. The evaporation vapor of the evaporation material 605 is heated secondly by the third heating wire 604 to increase the saturated vapor pressure inside the evaporation source 600 so that the evaporation vapor formed by the evaporation material 605 is injected from the spray nozzle 601 more uniformly, the temperature of the evaporation vapor is increased, it is difficult to form crystals in the spray nozzle 601, and the clogging problem is avoided.

Specifically, a portion of the third heating wire 604 is disposed in the first transmission chamber 6031 and another portion of the third heating wire 604 is disposed in the second transmission chamber 6032. The portion of the third heating wire 604 disposed in the second transmission chamber 6032 winds the inner plate 602.

Referring to FIG. 8, the detailed process of the evaporation of the evaporation material in the sixth embodiment of the present disclosure is carried out by mounting the first detector 610 at the position of the crucible 606, detecting the evaporation rate at the position of the crucible 606, and driving the lifting mechanism 607 to move the crucible 606 according to the detecting result, and thus controlling the evaporation rate. The detailed process is as follows.

The evaporation material is disposed in the crucible 606 and the evaporation material located on the heating surface 6051 is heated by the first heating wire 608 so that the evaporation material located on the heating surface 6051 is vaporized to form the evaporation vapor. The evaporation vapor passes through the crucible 606, the transmission chamber 603, and the first detecting channel 623, and reaches to the spray nozzle 601, and the evaporation vapor is injected from the spray nozzle 601.

First, the evaporation vapor passes through the crucible 606 and reaches the transmission chamber 603. The evaporation vapor is heated secondly by the third heating wire 604 of the transmission chamber 603 to increase the saturated vapor pressure inside the evaporation source 600 so that the evaporation vapor formed by the evaporation material is injected from the spray nozzle 601 more uniformly, the temperature of the evaporation vapor is increased, it is difficult to form crystals in the spray nozzle 601, and the clogging problem is avoided.

Then, the evaporation vapor passes through the first detecting channel 623 and the first detector 610 disposed at the first detecting channel 623 detects the evaporation rate of the evaporation vapor and compares it with the first predetermined evaporation rate. The lifting mechanism 607 drives the crucible 606 to move according to the comparison result. The specific movement mode is as follows.

The evaporation rate is increased in order to maintain the yield when the first evaporation rate detected by the first detector 610 is less than the first predetermined evaporation rate. More specifically, the lifting mechanism 607 drives the first heating wire 608 to move down, the distance between the crucible 606 and the first heating wire 608 is reduced, such that the heating effect of first heating wire 608 on the heating surface 6051 is improved. The first heating wire 608 is gradually advanced into the crucible 606 and the evaporation material through the heating surface 6051, which further increases the heating area of the first heating wire 608 and the evaporation material 605, thus increasing the evaporation rate of the evaporation material to reach the first predetermined evaporation rate.

When the first evaporation rate detected by the first detector 610 is greater than the first predetermined evaporation rate, it is necessary to reduce the evaporation rate in order to maintain the yield. More specifically, the lifting mechanism 607 drives the first heating wire 608 to move up, the lifting mechanism 607 controls the distance between the first heating wire 608 and the crucible 606 to be gradually increased, and the distance between the first heating wire 608 and the heating surface 6051 is accordingly increased so that the heating effect of the first heating wire 608 on the heating surface 6051 is reduced, thus reducing the evaporation rate of the evaporation material to the first predetermined evaporation rate.

Then, the first heating wire 608 heats the heating surface 6051 continuously so that the evaporation material disposed on the heating surface 6051 is gradually vaporized. The second heating wire 609 preheats the evaporation material in the crucible 606. The lifting mechanism 607 drives the first heating wire 608 to move down, the first heating wire 608 remains heating the evaporation material disposed on the heating surface 6051. The second heating wire 609 preheats the evaporation material in the crucible 606 so that the first heating wire 608 heats the heating surface 6051 to vaporize the evaporation material 605 and the evaporation rate of the evaporation material is ensured.

Therefore, the sixth embodiment of the present disclosure feeds back the detecting result of the first detector 610 to the lifting mechanism 607 in a timely manner, the lifting mechanism 607 controls the movement of the first heating wire 608 to change the distance between the heating surface 6051 formed by the evaporation material in the crucible 606 and the first heating wire 608 more timely and precisely, so as to control the heating efficiency of the first heating wire 608 on the heating surface 6051 more timely and precisely, further control the evaporation rate of the evaporation material more timely and precisely, prevent the evaporation material from cracking due to prolonged heating by the first heating wire 608, improve the yield of an OLED device, and improve the performance of the OLED device.

Referring to FIG. 9, a schematic view of the evaporation source in a seventh embodiment of the present disclosure is illustrated. The evaporation source 700 in a seventh embodiment of the present disclosure includes a casing 720, an inner plate 702, a crucible 706, a spray nozzle 701, a first heating wire 708, a lifting mechanism 707, and a second detector 711.

The seventh embodiment of the present disclosure is based on the improvement of the sixth embodiment, and the seventh embodiment of the present disclosure is different from the sixth embodiment in that the second detector 711 of the seventh embodiment of the present disclosure is disposed at the position of the spray nozzle 701, the first detector of the sixth embodiment of the present disclosure is disposed at the position of the crucible. The seventh embodiment of the present disclosure uses the second detector 711 instead of the first detector.

The inner plate 702, the crucible 706, the spray nozzle 701, the first heating wire 708, the lifting mechanism 707, the second heating wire 709, and the third heating wire 704 of the seventh embodiment of the present disclosure respectively have the same structure and effect as the inner plate 602, the crucible 606, the spray nozzle 601, the first heating wire 608, the lifting mechanism 607, the second heating wire 609, and the third heating wire 604 of the sixth embodiment of the present disclosure, and it will not be described again.

The casing 720 of the seventh embodiment of the present disclosure is different from the casing 620 of the sixth embodiment of the present disclosure in that the casing 720 of the seventh embodiment of the present disclosure does not dispose the first detecting channel. The first end 721 and the second end 722 of the casing 720, the first transmission chamber 7031 and the second transmission chamber 7032 of the transmission chamber 703 of the seventh embodiment of the present disclosure respectively have the same structure and effect as the first end 621 and the second end 622 of the casing, the first transmission chamber 6031 and the second transmission chamber 6032 of the transmission chamber 603 of the sixth embodiment of the present disclosure, and it will not be described again.

When the evaporation material 705 is heated in the crucible 706, the evaporation material 705 forms a heating surface 7051 in the crucible 706.

Specifically, the second detector 711 is disposed at the position of the spray nozzle 701 for detecting the rate of the spray nozzle 701 injecting the vapor (defined herein as a second evaporation rate). The lifting mechanism 707 drives the first heating wire 708 to move when the second detector 711 detects that the second evaporation rate of the spray nozzle 701 injecting the vapor is different from the second predetermined evaporation rate.

The seventh embodiment of the present disclosure compares the sixth evaporation rate detected by the second detector 711 with the second predetermined evaporation rate, the evaporation rate is increased in order to maintain the yield when the second evaporation rate detected by the second detector 711 is less than the second predetermined evaporation rate. More specifically, the lifting mechanism 707 drives the first heating wire 708 to move down, the distance between the crucible 706 and the first heating wire 708 is reduced, such as reducing the distance from the top of the crucible 706 to the bottom of the first heating wire 708, or reducing the distance from the center of the crucible 706 to the center of the first heating wire 708. It should be noted that the change in the distance between the crucible and the first heating wire of the embodiment of the present disclosure is relative to the same position. The distance between the first heating wire 708 and the heating surface 7051 is reduced, such as reducing the distance from the heating surface 7051 to the bottom of the first heating wire 708 or reducing the distance from the heating surface 7051 to the center of the first heating wire 708. It should be noted that the change in the distance between the heating surface and the first heating wire of the embodiment of the present disclosure is relative to the same position. The heating effect of first heating wire 708 on the heating surface 7051 is improved. The first heating wire 708 is gradually advanced into the crucible 706 and the evaporation material 705 through the heating surface 7051, which further increases the heating area of the first heating wire 708 and the evaporation material 705, thus increasing the evaporation rate of the evaporation material 705 to reach the second predetermined evaporation rate.

When the second evaporation rate detected by the second detector 711 is greater than the second predetermined evaporation rate, it is necessary to reduce the evaporation rate in order to maintain the yield. More specifically, the lifting mechanism 707 drives the first heating wire 708 to move up, the lifting mechanism 707 controls the distance between the first heating wire 708 and the crucible 706 to be gradually increased, and the distance between the first heating wire 708 and the heating surface 7051 is accordingly increased so that the heating effect of the first heating wire 708 on the heating surface 7051 is reduced, thus reducing the evaporation rate of the evaporation material to the second predetermined evaporation rate.

The second predetermined evaporation rate is the predetermined evaporation rate, which can be changed according to the specific requirements.

The seventh embodiment of the present disclosure feeds back the detecting result of the second detector 711 to the lifting mechanism 707 in a timely manner, the lifting mechanism 707 controls the movement of the crucible 706 to change the distance between the heating surface 7051 formed by the evaporation material in the crucible 706 and the first heating wire 708 more timely and precisely, so as to control the heating efficiency of the first heating wire 708 on the heating surface 7051 more timely and precisely, further control the evaporation rate of the evaporation material more timely and precisely, prevent the evaporation material from cracking due to prolonged heating by the first heating wire 308, improve the yield of an OLED device, and improve the performance of the OLED device.

In addition, since the second detector 711 is disposed at the position of the spray nozzle 701, the position of the spray nozzle 701 is closer to the substrate, and the rate of the evaporation vapor at the position of the spray nozzle 701 can be controlled more timely and accurately so that the evaporation vapor forming the film on the substrate is more uniform, and the heating effect is improved.

Referring to FIG. 9, the detailed process of the evaporation of the evaporation material in the seventh embodiment of the present disclosure is different from the detailed process of the evaporation of the evaporation material in the sixth embodiment of the present disclosure in that the evaporation source of the seventh embodiment of the present disclosure detects the evaporation rate by the second detector disposed at the position of the spray nozzle, see the second embodiment of the present disclosure for details, it will not be described again.

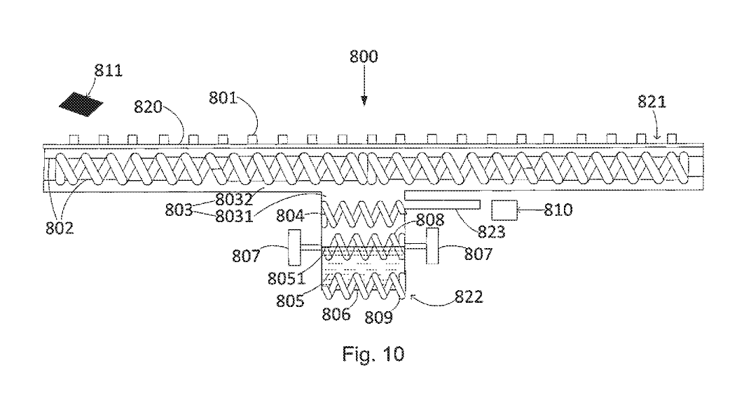

Refer to FIG. 10, which is a schematic view of the evaporation source in an eighth embodiment of the present disclosure. The evaporation source 800 in the eighth embodiment of the present disclosure includes a casing 820, an inner plate 802, a crucible 806, a spray nozzle 801, a first heating wire 808, a lifting mechanism 807, a first detector 810, and a second detector 811.

The eighth embodiment of the present disclosure is based on the improvement of the sixth embodiment and the seventh embodiment of the present disclosure, and the eighth embodiment of the present disclosure is different from the sixth embodiment in that the second detector 811 of the eighth embodiment of the present disclosure is disposed at the position of the spray nozzle 801 and the sixth embodiment of the present disclosure does not dispose the second detector.

The inner plate 802, the crucible 806, the spray nozzle 801, the first heating wire 808, the lifting mechanism 807, the second heating wire 809, the third heating wire 804, and the first detector 810 of the eighth embodiment of the present disclosure respectively have the same structure and effect as the inner plate 602, the crucible 606, the spray nozzle 601, the first heating wire 608, the lifting mechanism 607, the second heating wire 609, the third heating wire 604, and the first detector 610 of the sixth embodiment of the present disclosure, and it will not be described again.

The first end 821 and the second end 822 of the casing 820, the first transmission chamber 8031 and the second transmission chamber 8032 of the transmission chamber 803 of the eighth embodiment of the present disclosure respectively have the same structure and effect as the first end 621 and the second end 622 of the casing, the first transmission chamber 6031 and the second transmission chamber 6032 of the transmission chamber 603 of the sixth embodiment of the present disclosure, and it will not be described again.

When the evaporation material 805 is heated in the crucible 806, the evaporation material 805 forms a heating surface 8051 in the crucible 806.

In the eighth embodiment of the present disclosure, when the first evaporation rate detected by the first detector 810 is less than the first predetermined evaporation rate and the second evaporation rate detected by the second detector 811 is less than the second predetermined evaporation rate, the lifting mechanism 807 drives the first heating wire 808 to move down, such that the evaporation rate is increased in order to maintain the yield.

When the first evaporation rate detected by the first detector 810 is greater than the first predetermined evaporation rate and the second evaporation rate detected by the second detector 811 is greater than the second predetermined evaporation rate, the lifting mechanism 807 drives the first heating wire 808 to move up to reduce the evaporation rate.

When a detecting result of the first detector 810 is different from a detecting result of the second detector 811, the detecting result of the first detector 810 prevails. The first detector 810 is disposed at the position of the spray nozzle, so that the evaporation vapor injecting from the spray nozzle 801 can be uniform, and thus be prevented from impacting the OLED production and yield.

Further, when the detecting results of the first detector 810 and the second detector 811 are different, an alarm having a different detecting result of the first detector 810 and the second detector 811 is issued and displayed so that a worker can perform site inspection and maintenance.

The above is only a method in which the first detector 810 and the second detector 811 work together in the eighth embodiment of the present disclosure. In the eighth embodiment of the present disclosure, the first detector 810 and the second detector 811 may use other working methods, for example, when a detecting result of the first detector 810 is different from a detecting result of the second detector 811, the detecting result of the first detector 810 prevails.

The specific detecting result is different in that the first evaporation rate detected by the first detector 810 is less than the first predetermined evaporation rate and the second evaporation rate detected by the second detector 811 is greater than the second predetermined evaporation rate, or the first evaporation rate detected by the device 810 is greater than the first predetermined evaporation rate and the second evaporation rate detected by the second detector 811 is less than the second predetermined evaporation rate.

Similarly, the eighth embodiment of the present disclosure feeds back the detecting results of the first detector 810 and the second detector 811 to the lifting mechanism 807 in a timely manner, the lifting mechanism 807 controls the movement of the first heating wire 808 to change the distance between the heating surface 8051 formed by the evaporation material 805 in the crucible 806 and the first heating wire 808 more timely and precisely, so as to control the heating efficiency of the first heating wire 808 on the heating surface 8051 more timely and precisely, further control the evaporation rate of the evaporation material more timely and precisely, prevent the evaporation material 805 from cracking due to prolonged heating by the first heating wire 808, improve the yield of an OLED device, and improve the performance of the OLED device.

In addition, the first detector 810 is disposed at the position of the crucible 806 closer to the evaporation material 805, and the rate of the evaporation vapor at the position of the crucible 806 can be controlled more timely and accurately so that the evaporation vapor formed by the evaporation material 805 is more uniform, and the heating effect is improved.

In addition, the second detector 811 is disposed at the position of the spray nozzle 801, the position of the spray nozzle 801 is closer to the substrate, and the rate of the evaporation vapor at the position of the spray nozzle 801 can be controlled more timely and accurately so that the evaporation vapor forming the film on the substrate is more uniform, and the heating effect is improved.

The detailed process of the evaporation of the evaporation material in the eighth embodiment of the present disclosure is different from the detailed process of the evaporation of the evaporation material in the sixth embodiment of the present disclosure in that the evaporation source of the eighth embodiment of the present disclosure detects the evaporation rate by both of the second detector disposed at the position of the spray nozzle and the first detector disposed at the position of the first detecting channel, the heating effect is improved, see the sixth embodiment of the present disclosure for details, it will not be described again.

The present disclosure has been described with a preferred embodiment thereof. The preferred embodiment is not intended to limit the present disclosure, and it is understood that many changes and modifications to the described embodiment can be carried out without departing from the scope and the spirit of the invention that is intended to be limited only by the appended claims.

What is claimed is:

1. An evaporation source, comprising:
a casing comprising a first end, a second end opposite the first end, and a transmission chamber disposed between the first end and the second end;
a crucible configured to receive evaporation material, the evaporation material forming a heating surface on a surface in the crucible when the evaporation material is heated in the crucible, the crucible being disposed in the casing and positioned at the second end, and the crucible in communication with the transmission chamber;
a spray nozzle configured for injecting vapor formed by evaporating the evaporation material, the spray nozzle being disposed at the first end and in communication with the transmission chamber;
a first heating wire configured for heating the heating surface, the first heating wire directly fixed in the casing and positioned between the crucible and the spray nozzle;
a lifting mechanism movably connected to the casing, the lifting mechanism being fixed and connected to the crucible, the lifting mechanism controlling the crucible to move using the lifting mechanism movably connected to the casing, so as to vary positions of both the first heating wire and the heating surface and thus varying an evaporation rate generated using the first heating wire to heat the evaporation material;
a first detector disposed at a position of the crucible, configured for detecting an evaporation rate at the position of the crucible, the lifting mechanism driving the crucible to move when the first detector detects the evaporation rate at the position of the crucible being different from a first predetermined evaporation rate;
a second detector disposed at a position of the spray nozzle, configured for detecting a vapor injection rate of the spray nozzle, the lifting mechanism driving the crucible to move when the second detector detects the vapor injection rate of the spray nozzle being different from a second predetermined evaporation rate;
the lifting mechanism driving the crucible to move up when an evaporation rate detected by the first detector is less than the first predetermined evaporation rate and an evaporation rate detected by the second detector is less than the second predetermined evaporation rate;
the lifting mechanism driving the crucible to move down when the evaporation rate detected by the first detector is larger than the first predetermined evaporation rate and the evaporation rate detected by the second detector is larger than the second predetermined evaporation rate; and
wherein when a detecting result of the first detector is different from a detecting result of the second detector, the detecting result of the second detector prevails.

2. An evaporation source, comprising:
a casing comprising a first end, a second end opposite the first end, and a transmission chamber disposed between the first end and the second end;
a crucible configured to receive evaporation material, the evaporation material forming a heating surface on a surface in the crucible when the evaporation material is heated in the crucible, the crucible being disposed in the casing and positioned at the second end, and the crucible being in communication with the transmission chamber;
a spray nozzle configured for injecting vapor formed by evaporating the evaporation material, the spray nozzle being disposed at the first end and in communication with the transmission chamber;
a first heating wire configured for heating to the heating surface, the first heating wire being directly fixed in the casing, and the first heating wire being positioned between the crucible and the spray nozzle;
a lifting mechanism movably connected to the casing, the lifting mechanism being fixed and connected to the crucible, the lifting mechanism controlling the crucible to move using the lifting mechanism movably connected to the casing, so as to vary positions of both the first heating wire and the heating surface and thus varying an evaporation rate generated using the first heating wire to heat the evaporation material.

3. The evaporation source according to claim 2, wherein the evaporation source further comprises a first detector disposed at a position of the crucible, configured for detecting an evaporation rate at the position of the crucible, the lifting mechanism drives the crucible to move when the first detector detects the evaporation rate at the position of the crucible is different from a first predetermined evaporation rate.

4. The evaporation source according to claim 2, wherein the evaporation source further comprises a second detector disposed at a position of the spray nozzle, configured for detecting a vapor injection rate of the spray nozzle, the lifting mechanism drives the crucible to move when the second detector detects the vapor injection rate of the spray nozzle is different from a second predetermined evaporation rate.

5. The evaporation source according to claim 2, wherein the lifting mechanism controls a moving direction of the crucible to be perpendicular to the heating surface.

6. The evaporation source according to claim 2, wherein the evaporation source further comprises a second heating wire fixed in the crucible for heating the evaporation material.

7. The evaporation source according to claim 2, wherein the evaporation source further comprises a third heating wire fixed in the transmission chamber for heating vapor in the transmission chamber.

8. The evaporation source according to claim 7, wherein the transmission chamber comprises a first transmission chamber and a second transmission chamber in communication with each other, the first transmission chamber is near the crucible and is directly in communication with the crucible, the second transmission chamber is near the spray nozzle and is directly in communication with the spray nozzle, a portion of the third heating wire is disposed in the first transmission chamber, and another portion of the third heating wire is disposed in the second transmission chamber.

9. The evaporation source according to claim 8, wherein the evaporation source comprises an inner plate disposed in the second transmission chamber, and the portion of the third heating wire disposed in the second transmission chamber winds the inner plate.

10. The evaporation source according to claim 8, wherein the evaporation source further comprises a first detector disposed at a position of the crucible, configured for detecting an evaporation rate at the position of the crucible, the lifting mechanism drives the crucible to move when the first detector detects the evaporation rate at the position of the crucible is different from a predetermined evaporation rate, the casing has a first detecting channel, the first detecting channel is in communication with the first transmission chamber, and the first detector is disposed at a position of the first detecting channel.

11. The evaporation source according to claim 10, wherein the first detecting channel is extending outward from the first transmission chamber.

12. An evaporation source, comprising:
a casing comprising a first end, a second end opposite the first end, and a transmission chamber disposed between the first end and the second end;
a crucible configured to receive evaporation material, the evaporation material forming a heating surface on a surface in the crucible when the evaporation material is heated in the crucible, the crucible being disposed in the casing and positioned at the second end, and the crucible being in communication with the transmission chamber;
a spray nozzle configured for injecting vapor formed by evaporating the evaporation material, the spray nozzle being disposed at the first end and in communication with the transmission chamber;
a first heating wire configured for heating to the heating surface, the first heating wire being disposed in the casing, and the first heating wire positioned between the crucible and the spray nozzle; and
a lifting mechanism movably connected to the casing, the lifting mechanism being fixed and connected to the first heating wire, so as to vary positions of both the first heating wire and the heating surface and thus varying an evaporation rate generated using the first heating wire to heat the evaporation material.

13. The evaporation source according to claim 12, wherein the evaporation source further comprises a first detector disposed at a position of the crucible, configured for detecting an evaporation rate at the position of the crucible, the lifting mechanism drives the first heating wire to move when the first detector detects the evaporation rate at the position of the crucible different from a first predetermined evaporation rate.

14. The evaporation source according to claim 12, wherein the evaporation source further comprises a second detector disposed at a position of the spray nozzle, configured for detecting a vapor injection rate of the spray nozzle, the lifting mechanism drives the first heating wire to move when the second detector detects the vapor injection rate of the spray nozzle is different from a second predetermined evaporation rate.

15. The evaporation source according to claim 12, wherein the lifting mechanism controls a moving direction of the first heating wire to be perpendicular to the heating surface.

16. The evaporation source according to claim 12, wherein the evaporation source further comprises a second heating wire fixed in the crucible for heating the evaporation material.

17. The evaporation source according to claim 12, wherein the evaporation source further comprises a third heating wire fixed in the transmission chamber for heating vapor in the transmission chamber.

18. The evaporation source according to claim 17, wherein the transmission chamber comprises a first transmission chamber and a second transmission chamber in communication with each other, the first transmission chamber is near the crucible and is directly in communication with the crucible, the second transmission chamber is near the spray nozzle and is directly in communication with the spray nozzle, a portion of the third heating wire is disposed in the first transmission chamber, and another portion of the third heating wire is disposed in the second transmission chamber.

19. The evaporation source according to claim 18, wherein the evaporation source comprises an inner plate disposed in the second transmission chamber, and the portion of the third heating wire disposed in the second transmission chamber winds the inner plate.

20. The evaporation source according to claim 18, wherein the evaporation source further comprises a first detector disposed at a position of the crucible, configured for detecting an evaporation rate at the position of the crucible, the lifting mechanism drives the first heating wire to move when the first detector detects the evaporation rate at the position of the crucible is different from a predetermined evaporation rate, the casing has a first detecting channel, the first detecting channel is in communication with the first transmission chamber, the first detector is disposed at a position of the first detecting channel, and the first detecting channel extends outward from the first transmission chamber.
